(19) United States
(12) Patent Application Publication
(10) Pub. No.: US 2018/0358145 A1
(43) Pub. Date: Dec. 13, 2018

(54) BENDABLE ELECTRICAL CONDUCTOR IN A THERMOFORMED ARTICLE

(71) Applicant: E I DU PONT DE NEMOURS AND COMPANY, Wilmington, DE (US)

(72) Inventors: Daniel Aneurin Inns, Palo Alto, CA (US); Jeffrey J. G. Dee, San Jose, CA (US)

(21) Appl. No.: 15/969,144

(22) Filed: May 2, 2018

Related U.S. Application Data
(60) Provisional application No. 62/516,339, filed on Jun. 7, 2017.

(51) Int. Cl. H01B 1/22; H05K 1/02; H05K 1/09; H05K 3/12; H01B 5/14

(52) U.S. Cl. CPC H01B 1/22; H05K 1/028; H05K 1/095; H01B 3/302; H01B 5/14; H05K 2201/0338; H05K 3/12

(57) ABSTRACT

This invention is related to a thermoformed article containing a bendable region traversed by an electrical conductor, the electrical conductor comprising a substrate and a two-layer electrical conductor. The two-layer conductor comprises (a) a layer of polymer thick film silver conductor comprising a polymer selected from the group consisting of (i) a mixture of thermoplastic polyurethane and thermoplastic polyhydroxyether and (ii) a thermoplastic polyurethane having a percent elongation of at least 200% and a tensile stress necessary to achieve 100% elongation of less than 1000 pounds per square inch and (b) a layer of polymer thick film silver conductor comprising thermoplastic polyhydroxyether.

### FIELD OF THE INVENTION

This invention is directed to a thermoformed article containing a bendable region traversed by a bendable electrical conductor.

### BACKGROUND OF THE INVENTION

There is interest in incorporating electrical conductors in flexible and bendable articles. If a conductor is formed by printing a paste and the resistance of the conductor increases beyond acceptable limits as a result of thermoforming or bending, a second layer of the paste is printed so that the resistance of the initially formed conductor is lower. Typically, this will be acceptable initially but the mechanical limitations of the conductor under fatigue testing will become evident.

There is a need for an electrical conductor in an article that undergoes laminating, embossing or thermoforming in addition to the flexing and bending during the life cycle of the article without undergoing a large change in resistance.

### SUMMARY OF THE INVENTION

This invention relates to a thermoformed article having a bendable region traversed by an electrical conductor.

The invention provides a thermoformed article containing a bendable region traversed by an electrical conductor, the electrical conductor comprising:

(a) a substrate; and

(b) a two-layer electrical conductor comprising:
a. a layer A of polymer thick film silver conductor comprising a polymer selected from the group consisting of (i) a mixture of thermoplastic polyurethane and thermoplastic polyhydroxyether and (ii) a thermoplastic polyurethane having a percent elongation of at least 200% and a tensile stress necessary to achieve 100% elongation of less than 1000 pounds per square inch; and
b. a layer B of polymer thick film silver conductor comprising thermoplastic polyhydroxyether;
wherein either layer A is printed directly on the substrate as a bottom layer and layer B is printed on layer A as a top layer of the electrical conductor or layer B is printed directly on the substrate as a bottom layer and layer A is printed on layer B as a top layer of the electrical conductor.

The thermoformed electrical conductor has a final resistance R_{f} after being subjected to the 180° bending test and an initial resistance Rᵢ prior to the 180° bending test.

In one embodiment, the polymer of layer A comprises a mixture of thermoplastic polyurethane and thermoplastic polyhydroxyether and the ratio R_{f}/Rᵢ is less than 10.

### DETAILED DESCRIPTION OF THE INVENTION

The invention relates to a thermoformed article containing a bendable region traversed by an electrical conductor, the electrical conductor comprising a substrate and a two-layer electrical conductor comprising a layer A of polymer thick film silver conductor comprising a polymer selected from the group consisting of (i) a mixture of thermoplastic polyurethane and thermoplastic polyhydroxyether and (ii) a thermoplastic polyurethane having a percent elongation of at least 200% and a tensile stress necessary to achieve 100% elongation of less than 1000 pounds per square inch; and a layer B of polymer thick film silver conductor comprising thermoplastic polyhydroxyether.

In one embodiment layer A is printed directly on the substrate as a bottom layer and layer B is printed on layer A as a top layer of the electrical conductor

In another embodiment layer B is printed directly on the substrate as a bottom layer and layer A is printed on layer B as a top layer of the electrical conductor.

In one embodiment the top layer of polymer thick film conductor extends along the complete length of the bottom layer of thick film conductor.

In another embodiment the top layer of polymer thick film conductor extends along only a portion of the bottom layer of thick film conductor, the portion including the bendable region of the thermoformed article.

The substrate for the electrical conductor may be a portion of the article itself. In another embodiment the substrate is a separate entity onto which the two-layer electrical conductor is printed and the substrate is then attached to the article. The substrate may be a fabric, particularly a fabric with a urethane coating.

The article with the two-layer electrical conductor may be prepared by printing polymer thick film silver pastes.

The paste used to form layer A of polymer thick film conductor typically comprises silver in the form of powder or flakes, a polymer selected from the group consisting of (i) a mixture of thermoplastic polyurethane and thermoplastic polyhydroxyether and (ii) a thermoplastic polyurethane having a percent elongation of at least 200% and a tensile stress necessary to achieve 100% elongation of less than 1000 pounds per square inch, and a solvent. A drying step after printing removes the solvent and results in layer A. The thermoplastic polyurethane of polymer thick film conductor is selected from the group consisting of a urethane homopolymer, a polyester-based copolymer and a linear hydroxyl polyurethane. In one embodiment the polymer comprises a mixture of thermoplastic polyurethane and thermoplastic polyhydroxyether. In another embodiment the polymer comprises a thermoplastic polyurethane having a percent elongation of at least 200% and a tensile stress necessary to achieve 100% elongation of less than 1000 pounds per square inch.

The paste used to form layer B of polymer thick film conductor typically comprises silver in the form of powder or flakes, thermoplastic polyhydroxyether and a solvent. A drying step after printing removes the solvent and results in layer B.

Generally, a thick film composition comprises a functional phase that imparts appropriate functional properties to the composition. For example, the functional phase may comprise electrically functional powders such as silver dispersed in an organic medium that acts as a carrier for the functional phase. Generally, the composition is fired to burn out both the polymer and the solvent of the organic medium and to impart the electrically functional properties. However, in the case of a polymer thick film composition, the polymer portion of the organic medium remains as an integral part of the conductor composition after drying to remove the solvent. Therefore, the choice of the polymer is important in determining the properties of the polymer thick film conductor.

Thermoplastic polymers become moldable above a specific temperature and solidify when cooled and can be reheated and remolded and thus may be reshaped by heating.

Thermoforming is a manufacturing process in which a material is heated to a pliable temperature and then formed to a specific shape in a mold. As used herein thermoforming refers to the usual thermoforming as well as embossing on articles by stamping or molding and lamination by heat and/or pressure.

### EXAMPLES

Some examples were tested using a simple bending test. The polymer of layer A was a mixture of thermoplastic polyurethane and thermoplastic polyhydroxyether. In one sample a layer A was deposited on a substrate as the bottom layer and a layer B deposited on layer A as the top layer—substrate/A/B. In a second sample a layer B was deposited on a substrate as the bottom layer and a layer A was deposited on layer B as the top layer—substrate/B/A. The samples were then thermoformed. Each sample was then bent 180° over a 4 mm diameter bending surface first in one direction and then 180° in the opposite direction while continuously monitoring the resistance of each two-layer conductor. This is one cycle of what is referred to herein as the 180° bending test. The 180° bending test consisted of 120 such cycles. Each cycle takes about one second and the resistance goes through a maximum with each cycle. The maximum increases with the increasing number of cycles. However, the resistance recovers to a lower resistance in less than 20 seconds when the bending is stopped. Each sample had an initial resistance Rᵢ prior to the test and a final (recovered) resistance of R_{f} after being subjected to the 120 cycles of the 180° bending test. The initial resistance Rᵢ of the substrate/A/B sample was 0.5 ohms and the resistance ratio R_{f}/Rᵢ was 5.8. The initial resistance Rᵢ of the substrate/B/A sample was 0.6 ohms and the resistance ratio R_{f}/Rᵢ was 8.6.

### COMPARATIVE EXPERIMENT A

For comparison another sample was prepared with two layers of the same polymer thick film conductor, i.e., both the bottom and the top layer were layer B-substrate/B/B. The sample was then thermoformed. The sample was subjected to the 180° bending test. The initial resistance Rᵢ of the sample was 0.5 ohms and the resistance ratio R_{f}/Rᵢ was 46.1.

What is claimed is:

1. A thermoformed article containing a bendable region traversed by an electrical conductor, the electrical conductor comprising:
(a) a substrate; and
(b) a two-layer electrical conductor comprising:
a. a layer A of polymer thick film silver conductor comprising a polymer selected from the group consisting of (i) a mixture of thermoplastic polyurethane and thermoplastic polyhydroxyether and (ii) a thermoplastic polyurethane having a percent elongation of at least 200% and a tensile stress necessary to achieve 100% elongation of less than 1000 pounds per square inch; and
b. a layer B of polymer thick film silver conductor comprising thermoplastic polyhydroxyether;
wherein either layer A is printed directly on the substrate as a bottom layer and layer B is printed on layer A as a top layer of the electrical conductor or layer B is printed directly on the substrate as a bottom layer and layer A is printed on layer B as a top layer of the electrical conductor.

2. The article of claim 1, the polymer of layer A consisting of a mixture of thermoplastic polyurethane and thermoplastic polyhydroxyether.

3. The article of claim 2, wherein the thermoformed electrical conductor has a final resistance R_{f} after being subjected to the 180° bending test and an initial resistance Rᵢ prior to the test and the ratio R_{f}/Rᵢ is less than 10.

4. The article of claim 1, wherein the thermoplastic polyurethane of polymer thick film conductor A is selected from the group consisting of a urethane homopolymer, a polyester-based copolymer and a linear hydroxyl polyurethane.

5. The article of claim 1, wherein layer A is printed directly on the substrate as a bottom layer and layer B is printed on layer A as a top layer of the electrical conductor.

6. The article of claim 1, wherein layer B is printed directly on the substrate as a bottom layer and layer A is printed on layer B as a top layer of the electrical conductor.

7. The article of claim 1, wherein the top layer of polymer thick film conductor extends along the complete length of the bottom layer of polymer thick film conductor.

8. The article of claim 1, wherein the top layer of polymer thick film conductor extends along only a portion of the bottom layer of thick film conductor, the portion including the bendable region of the thermoformed article.
